(19) United States
(12) Patent Application Publication
(10) Pub. No.: US 2011/0083723 A1
(43) Pub. Date: Apr. 14, 2011

(54) SOLAR ENERGY REFLECTOR AND ASSEMBLY

(76) Inventor: Humayun Akhter Mughal, Essex (GB)

(21) Appl. No.: 12/997,314

(22) PCT Filed: Jun. 11, 2009
(86) PCT No.: PCT/GB09/50659

§ 371 Date: Dec. 10, 2010

(30) Foreign Application Priority Data
Jun. 11, 2008 (GB) 0810676.7
Jun. 11, 2008 (GB) 0810677.5
Jun. 11, 2008 (GB) 0810679.1
Jun. 11, 2008 (GB) 0810680.9
Jun. 11, 2008 (GB) 0810683.3

(51) Int. Cl. H01L 31/052

(52) U.S. Cl. 136/246

(57) ABSTRACT

A reflector 11 for directing solar radiation on to energy converters provided within a defined area 14. The reflector is arranged for location around said area with a lower edge 18 of the reflector positioned adjacent the periphery of said area, the reflector comprising a panel formed of a material substantially transparent to solar radiation and having a front face 24 on to which solar radiation is incident. Behind the front face, the reflector is formed to have a plurality of prismatic units 25 within which total internal reflection of radiation incident on the front face takes place. In use solar radiation incident on the front face of the reflector is reflected within the reflector by the prismatic units to be directed on to the energy converters.

There is also provided a solar energy assembly for collecting and converting solar energy, which assembly comprises a substrate 13 supporting an array of energy converters 11, a frame 12 mounted on the substrate to extend around at least some or part of the energy converters, and a reflector, as described above, carried by the frame and having at least one reflecting panels arranged to reflect incident solar energy on to the converters.

This invention relates to a reflector for directing incident solar energy on to energy converters provided within a defined area associated with the reflector. This invention also relates to a solar energy assembly utilising such reflectors for collecting and converting solar energy. In a preferred aspect, this invention relates to a solar energy assembly comprising a plurality of individual reflectors which direct solar energy on to a corresponding plurality of arrays of photovoltaic cells.

With increasing energy costs and environmental pollution, ever more emphasis is being placed on renewable energy and the extraction of energy from natural sources. A particular area of development concerns solar energy where sunlight (that is, the radiation energy from the sun) is used either directly to heat a fluid such as water or is incident upon photovoltaic cells in order to generate electricity from the incident radiation.

Though it is possible to allow matt black tubes simply to absorb incident solar energy to effect heating of water passing through the tubes, greatly enhanced results can be obtained by collecting solar energy over a large area and reflecting that energy on to a relatively small area where the energy is converted for use. Good results can still be obtained even with relatively low collection ratios—that is to say the ratio of the area over which energy is collected to the area on which that energy is directed by the reflector. In view of increasing energy costs, it is therefore worthwhile designing solar energy collectors with collection ratios as low as 4:1 and still a good return on the capital investment may be achieved.

A known problem associated with solar energy reflectors is that of atmospheric pollution as well as the direct depositing of airborne detritus and grime which results in a degradation in the performance of the reflecting surface and so in turn the efficiency of the conversion of the incident solar radiation to useful energy. In order to address this problem, it is necessary frequently to clean the reflecting surfaces else the reflecting efficiency quickly falls so leading to a reduction in output of the solar energy converter. However, cleaning considerably adds to the maintenance cost and it would be advantageous to minimise the amount and frequency of cleaning required, as well as to increase the speed at which cleaning can be effected.

Further, through a variety of causes, it can happen that a solar energy collector may become damaged for example by impact and in that event, additional maintenance may be required. To that end, it would be advantageous to allow the replacement of a relatively small reflector unit rather than to have to replace a relatively large-scale solar reflector.

Having regard to the above, it is a principal aim of the present invention to provide a reflector, or solar energy assembly including reflectors for use in a solar energy converter which are inexpensive to manufacture, highly efficient and moreover resistant to degradation through the effects of atmospheric pollution and so on.

According to a first aspect of this invention, there is provided a reflector for directing solar radiation on to energy converters provided within a defined area, which reflector is arranged for location around said area with a lower edge of the reflector positioned adjacent the periphery of said area, the reflector comprising a panel formed of a material substantially transparent to solar radiation and having a front face on to which solar radiation is incident, and behind the front face the reflector is formed to have a plurality of prismatic units within which total internal reflection of radiation incident on the front face takes place whereby in use solar radiation incident on the front face of the reflector is reflected within the reflector by the prismatic units to be directed on to the energy converters.

It will be appreciated that with the reflector of this invention, reflection of incident solar energy occurs through total internal reflection by the prismatic units on the rear of the reflecting panel. Thus, no mirror as such is provided and so there is no reflective layer on the panel which otherwise would be subject to degradation, possible corrosion and other effects which would reduce the efficiency of the layer.

Preferably, each prismatic unit comprises a rib of substantially triangular cross-sectional shape extending across the panel. To optimise the total internal reflection, each such rib should have an included angle of substantially 90° between the flanks defining the rib. Further, to maximise the collection of solar radiation and direct that radiation on to the energy converters, each rib should extend from the lower edge of the panel to an opposed upper edge thereof, with each rib extending in alignment with a perpendicular to said defined area carrying the energy converters.

It is possible in a different aspect of the invention to instead use a reflector that relies at least in part on mirroring rather that total internal reflection. Therefore according to a second aspect of this invention, there is further provided a reflector for directing solar energy on to energy converters provided within a defined polygonal area, which reflector comprises a plurality of generally rectangular main panels each having a lower edge for locating adjacent an edge of said polygonal area, each main panel also having a pair of side edges extending from and generally normal to the associated lower edge and each main panel flaring outwardly from said area, and a plurality of secondary panels each having an adjacent pair of first edges meeting at the lower corner adapted to locate at the junction between the lower edges of two adjacent main panels with the first edges of the secondary panels substantially mating with the side edges of said two adjacent main panels, each of the main and secondary panels being formed as a solar energy reflector whereby in use incident solar energy is directed on to the energy converters.

In this aspect of the invention the main and secondary panels could be mirrored in order to have reflective properties, for example by coating with a metal such as aluminium. That metallic coating could be on the front face of each panel and on which solar radiation is incident, but long term better results could be expected with a coating on the rear face of each panel since the panel itself will give protection to the reflecting surface of that coating.

A preferred form of reflector of both those aspects of this invention comprises a plurality of generally rectangular main panels each having a lower edge for locating adjacent an edge of the area of energy converters, each main panel also having a pair of side edges extending from and generally normal to the associated lower edge and each main panel flaring outwardly from said area, and a plurality of secondary panels each having an adjacent pair of first edges meeting at a lower corner adapted to locate at the junction between the lower edges of two adjacent main panels, with the first edges of each secondary panel substantially mating with the side edges of the two adjacent main panels.

The area defined by the upper edges of the main and secondary panels may be substantially square-shaped in plan, with the main panels flaring outwardly at an angle within the range of 55° to 65° and preferably at substantially 60° relative to a perpendicular from the plane of the frame.

The solar energy converters may comprise a heat exchanger having heat exchanger tubes through which a heat exchange fluid (preferably water or an aqueous solution) is caused to run. In this case, the tubes may extend over the entire area of the substrate which is divided into sub-areas by the frames also mounted on the substrate with each sub-area receiving reflected radiation. In the alternative, the array of energy converters may comprise an array of photovoltaic cells and in this case, the array may be wholly surrounded by the frame. Preferably, the substrate supports a plurality of similar arrays of photovoltaic cells and there is provided a like plurality of frames each surrounding a respective array of photovoltaic cells and having associated therewith a respective reflector.

The reflector may be used in conjunction with a frame surrounding the solar energy converters with both the frame and the converters mounted on a substrate. The reflector may be releasably supported by the frame such that removal of the reflector for cleaning or replacement is relatively easy to perform, so minimising down-time in the event that maintenance is required.

Advantageously, each panel is made of an optically transparent plastics material though inevitably there will be some attenuation of solar radiation passing through the material. It is found that polycarbonate is a particularly suitable material to use for each panel since it is durable, optically transparent and allows the formation of the prismatic units referred to above on the rear face of the panel.

For a reflector made up from a plurality of panels as described above, the area defined by the upper edges of the main and secondary panels may be substantially square-shaped, in plan. For a case in which the substrate supports a plurality of similar arrays of photovoltaic cells and there is a like plurality of frames each surrounding a respective array and having associated therewith a respective reflector, the upper edge of a main panel of one reflector advantageously lies closely adjacent the upper edge of a main panel of an adjacent reflector. In this way, the highest possible packing density for the reflectors can be achieved, so optimising the collection of solar energy for a solar energy assembly of a given area.

According to a third aspect of this invention there is provided a solar energy assembly for collecting and converting solar energy, which assembly comprises a substrate supporting an array of energy converters, a frame mounted on the substrate to extend around at least some or part of the energy converters, and a reflector carried by the frame and arranged to reflect incident solar energy on to the converters.

The features of the reflector may be as described above, so for example the reflector may be releasably supported by the frame so as to be readily separable therefrom.

It will be appreciated that with such a solar energy assembly, there is provided a compact arrangement including a substrate supporting one or more energy converters, and a frame which releasably supports a separate reflector.

Advantageously, there is at least one releasable clip which secures the reflector to the frame, but which when released, frees the reflector from the frame. It would be possible to provide the reflector with a lug which interengages with an opening in the frame, or vice versa, at a location opposed to the releasable clip, such that releasing of the clip allows the reflector to be moved away from the frame and unhooked therefrom. The preferred arrangement is for there to be more than one releasable clip for holding the reflector to the frame such that two or more of the clips must be released in order to allow the reflector to be removed from the frame.

In a preferred embodiment, the frame is of generally rectangular shape and there is a releasable clip provided in each corner region of the frame. Thus, there will be four releasable clips for the rectangular frame though it may be possible to release a reflector by releasing two adjacent clips and then unhooking the reflector from the other two releasable clips without effecting releasing movement of those other two clips. Such an arrangement is particularly advantageous in the case of an array of closely juxtaposed reflector assemblies distributed over a substrate, since access to all of the clips of a frame may be restricted by the other reflector assemblies. Access to two adjacent clips is more likely to be available than to all four clips of the assembly.

Each clip conveniently comprises a resiliently flexible catch member having a catch surface engageable with a lug projecting from the reflector. Resilient deflection of the catch member from its normal position will release the lug from the catch surface. A ramp surface may be provided on the catch member such that moving the reflector into engagement with the frame brings the lug into engagement with the ramp surface so as then to deflect the catch member sufficiently to allow the lug to move behind the catch surface and thereafter to be held by the catch member, until the clip is released once more.

For a reflector made up from a plurality of panels as described above, the area (in plan) defined by the upper edges of the main and secondary panels may be substantially square-shaped. For a case in which the substrate supports a plurality of similar arrays of photovoltaic cells and there is a like plurality of frames each surrounding a respective array and having associated therewith a respective reflector, the upper edge of a main panel of one reflector advantageously lies closely adjacent the upper edge of a main panel of an adjacent reflector. In this way, the highest possible packing density for the reflectors can be achieved, so optimising the collection of solar energy for a solar energy assembly of a given area.

According to a fourth aspect of the present invention there is provided a reflector assembly for directing solar radiation on to energy converters provided within a defined area, which reflector assembly comprises a frame adapted for mounting to extend around said area and a reflector having a plurality of reflecting panels and arranged to be carried by the frame so as to reflect incident solar energy on to the converters, and there being at least one releasable clip for securing the reflector to the frame. The frame is as described earlier with respect to the other aspects of the invention.

To achieve maximum efficiency the reflectors and assemblies need to maintain the optimum alignment to the sun at all times, because angular misalignment can reduce the amount of solar energy collected. However the sun is constantly moving across the sky and is only optimally directed at a fixed panel for a brief period during the day. Therefore it is desirable that to have assemblies that track the sun. Whilst this has been done before, existing mechanisms for the tracking the panels require expensive components which prohibits their wide application.

The solar energy assembly may further include a tracking assembly to move it relative to a mounting, the tracking assembly comprising a crank, a first linear actuator connected to the mounting and the crank and a second linear actuator connected to the crank and the solar panel, whereby linear extension or contraction of one or both actuators causes rotational movement of the panel relative to the mounting about a first axis.

The purpose of the tracking assembly is to move a solar energy assembly relative to its mounting in order that it can follow the passage of the sun during the day. The solar energy assembly must be mobile and needs to be directed towards the sun to achieve maximum efficiency.

The crank needs to be able to rotate and to couple the linear movement of the first and second actuators. It is possible for the crank to be pivotally connected to the mounting or the panel; however it is advantageous to have the crank connected to the mounting.

Movement of the first linear actuator may cause rotation of the crank about its connection to the mounting. This causes the second actuator to move, even if it is not altering in overall length, which in turn moves the panel to which the second actuator is attached. The first linear actuator may be connected to the crank at a first point and the second linear actuator may be connected to the crank at a second point. Both such points are spaced from each other and are radially spaced from the axis of rotation of the crank. Therefore rotation of the crank causes curved movement of both the actuator connection points. The crank may take the form of a bell crank.

The tracking assembly may be provided with a further actuator to move the panel about a second axis generally at right angles to the first axis. This further actuator may include one or more linear actuator. It may be equivalent to the combination of first actuator, crank and second actuator. Alternatively it may comprise a single linear or alternative actuator.

The first axis is often generally vertical and rotational movement about that axis causes horizontal tracking of the solar panel. Such horizontal tracking must be made through a wide arc (sometime around 180°) as the sun moves a long way around the horizon during the day. The second axis may be generally horizontal such that rotation thereabout causes vertical tracking of the solar panel. The range of vertical tracking need not be as large, with a range of 90° usually sufficient.

The mounting may be formed in two relatively moveably parts with an upper portion that is pivotally mounted to a lower portion. The movement of the upper portion (also referred to as a sub-frame) with respect to the lower portion (also referred to as a support pillar) can be achieved by the further actuator to effect vertical tracking of the panel. The panel may be pivotally connected to the upper portion with the first linear actuator, crank and second linear actuator moving the panel with respect to the upper portion. In such an arrangement the crank and first linear actuator are connected to the upper portion.

The tracking assembly provides a wide arc of movement but is made from simple and cheap components. The prior art in contrast requires complex expensive actuators to move a panel through a similar wide arc.

The tracking assembly discussed above can also be used in solar assemblies other than those described above, consequently according to a fifth aspect of the present invention there is further provided a tracking assembly to move a solar panel relative to a mounting, comprising a crank, a first linear actuator connected to the mounting and the crank and a second linear actuator connected to the crank and the solar panel, whereby linear extension or contraction of one or both actuators causes rotational movement of the panel relative to the mounting about a first axis. This tracking assembly may have the same features as described above.

By way of example only, one specific embodiment of a solar energy reflector assembly in a solar energy assembly arranged in accordance with this invention will now be described in detail, reference being made to the accompanying drawings in which:-

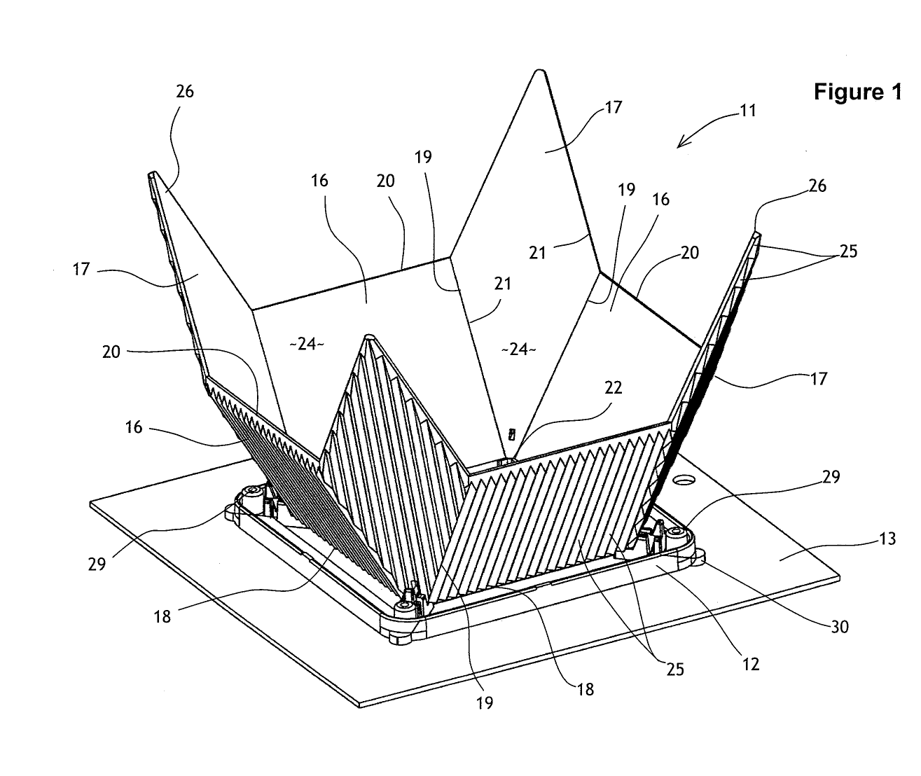

FIG. 1 is an isometric view of the reflector assembly;

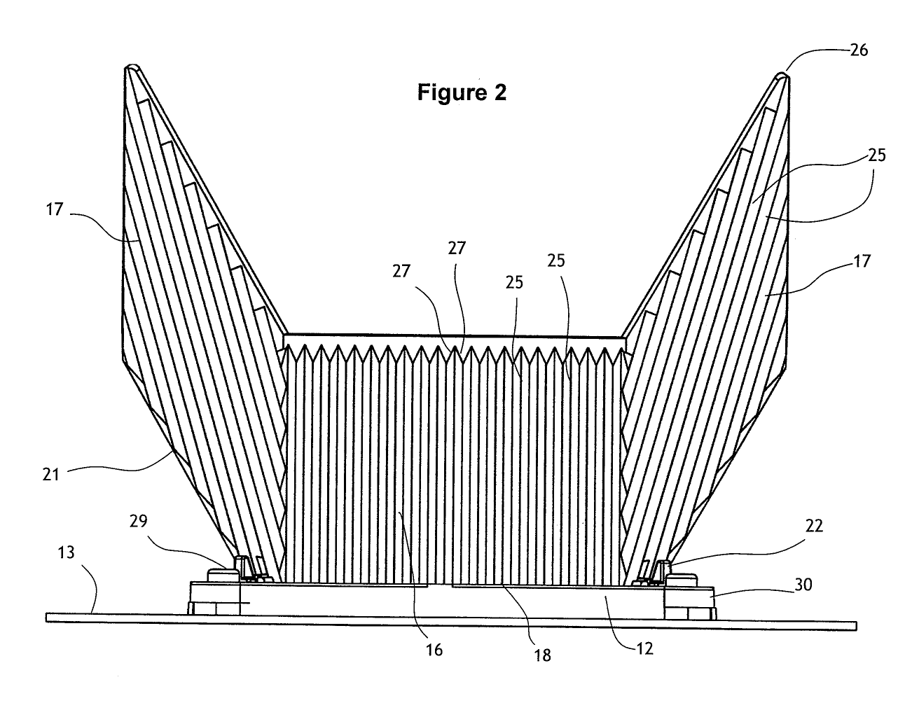

FIG. 2 is a front view on the assembly of FIG. 1;

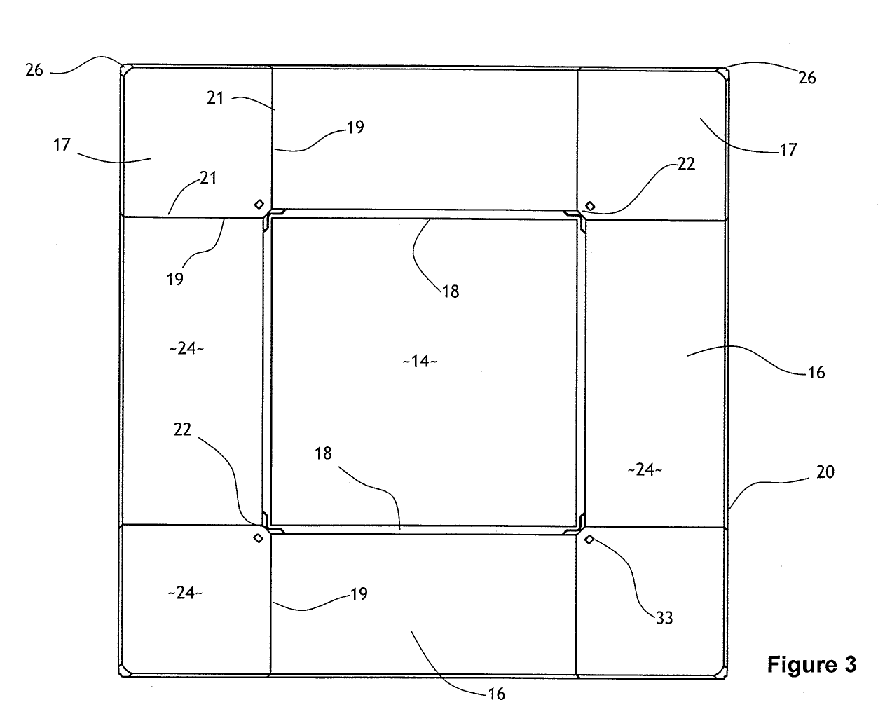

FIG. 3 is a plan view on the assembly;

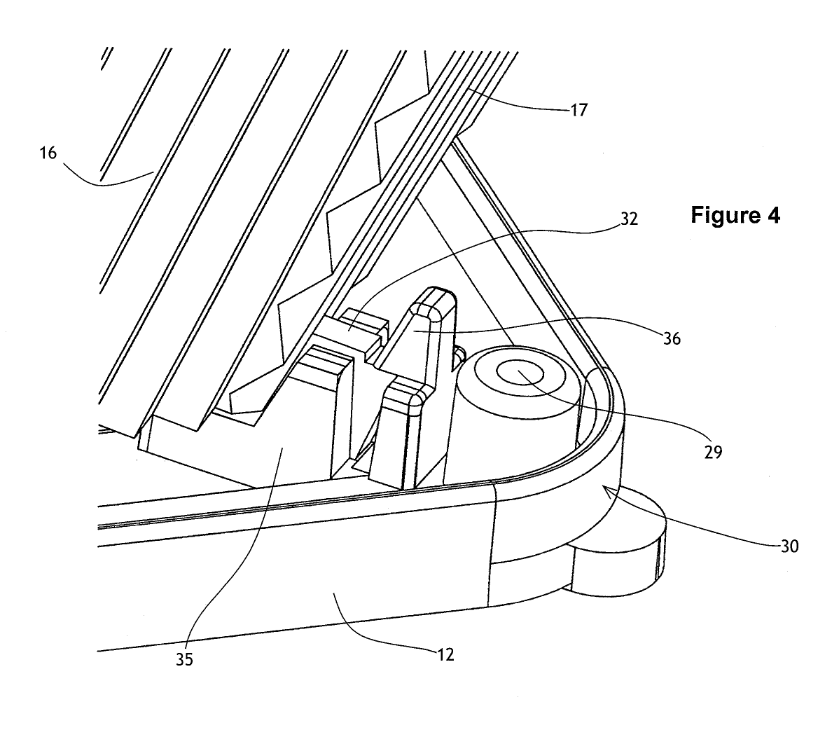

FIG. 4 is a detailed view on an enlarged scale of a connection between the reflector and a frame therefor, as used in the reflector assembly of FIG. 1;

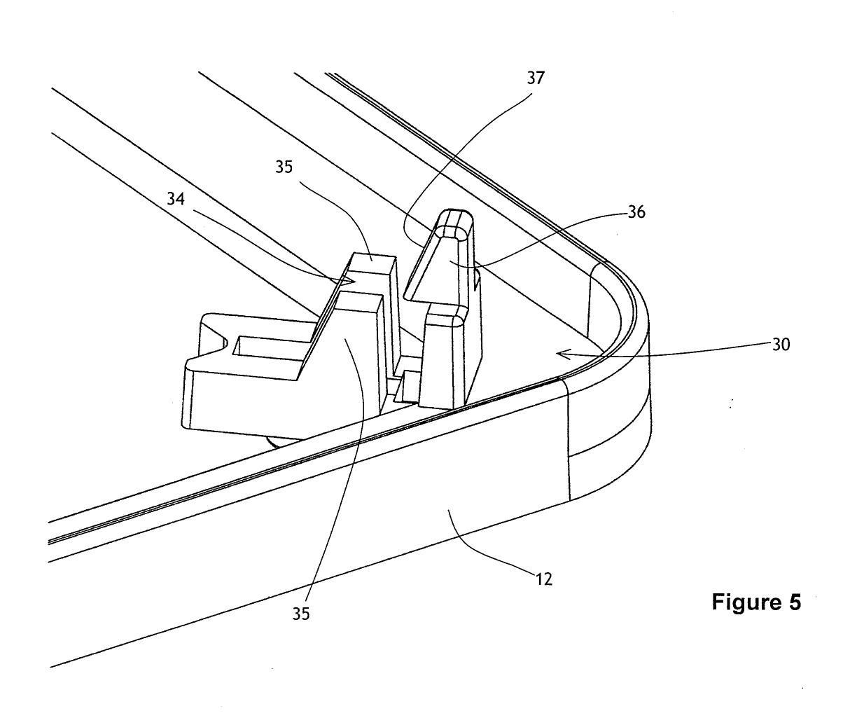

FIG. 5 is an isometric view on the corner region of the frame;

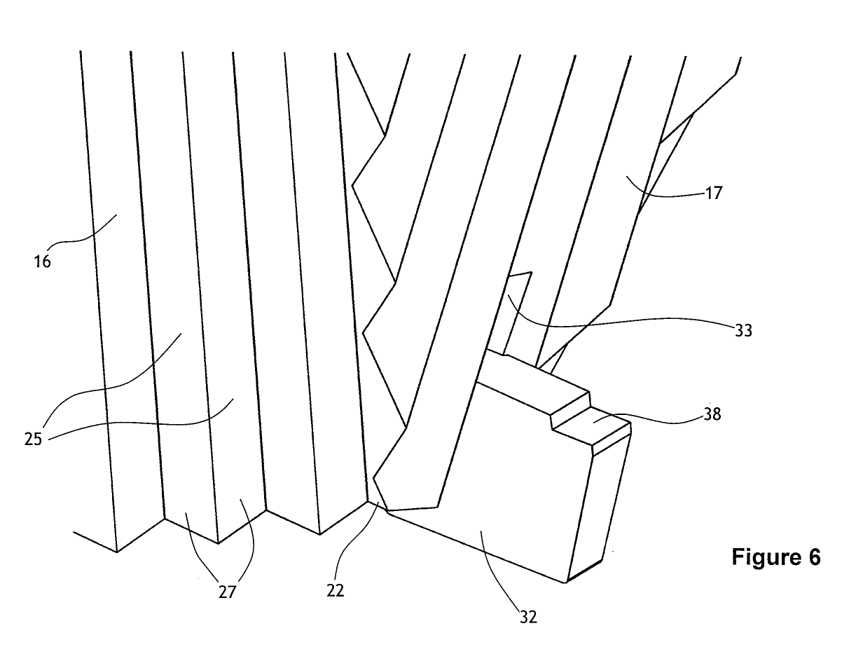

FIG. 6 is an isometric view on the corner region of the reflector;

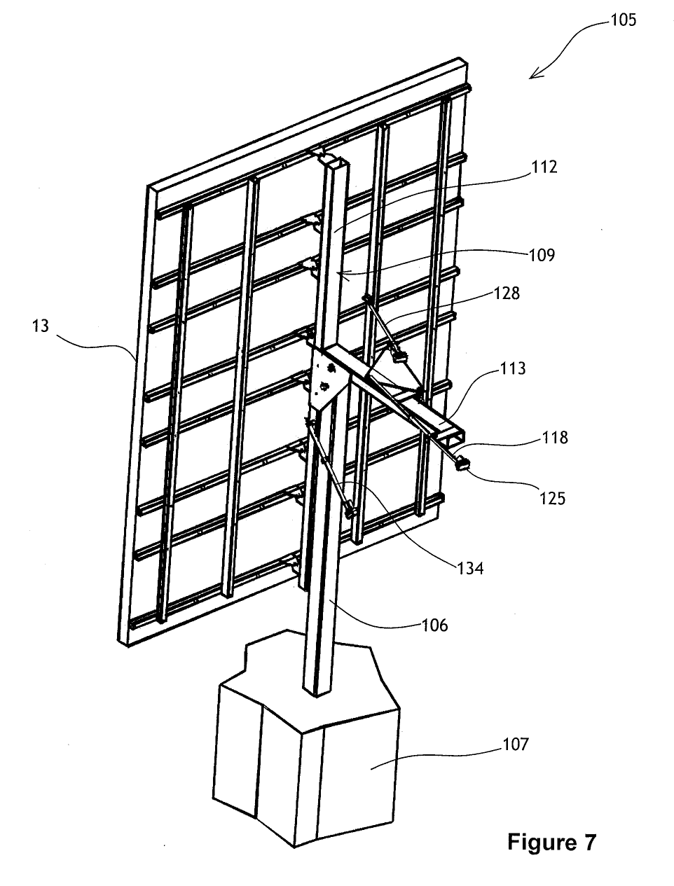

FIG. 7 is perspective view of a solar energy assembly including multiple reflectors (although not visible in this view) provided with a tracking assembly;

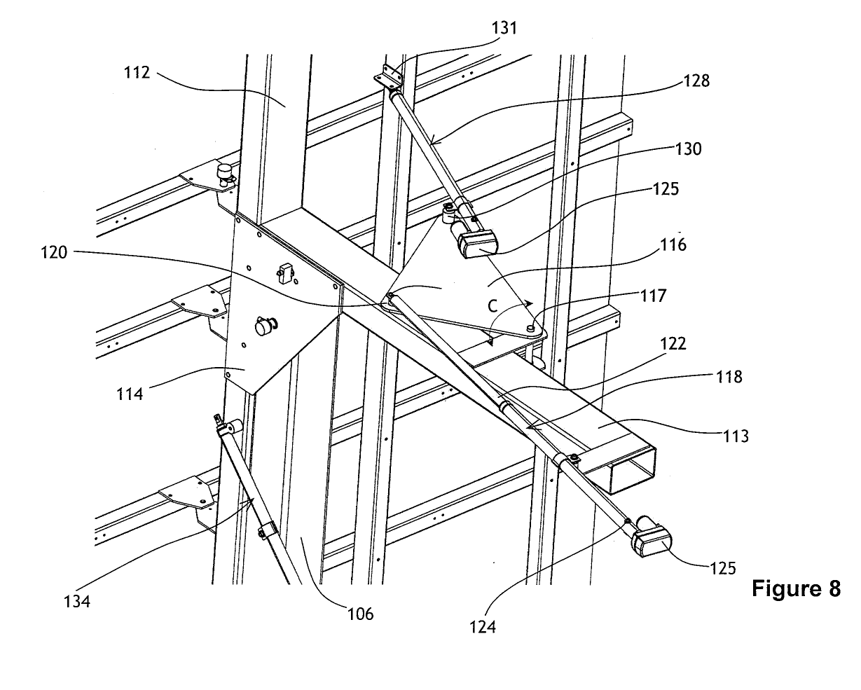

FIG. 8 is an enlarged perspective view of the tracking assembly of FIG. 7; and

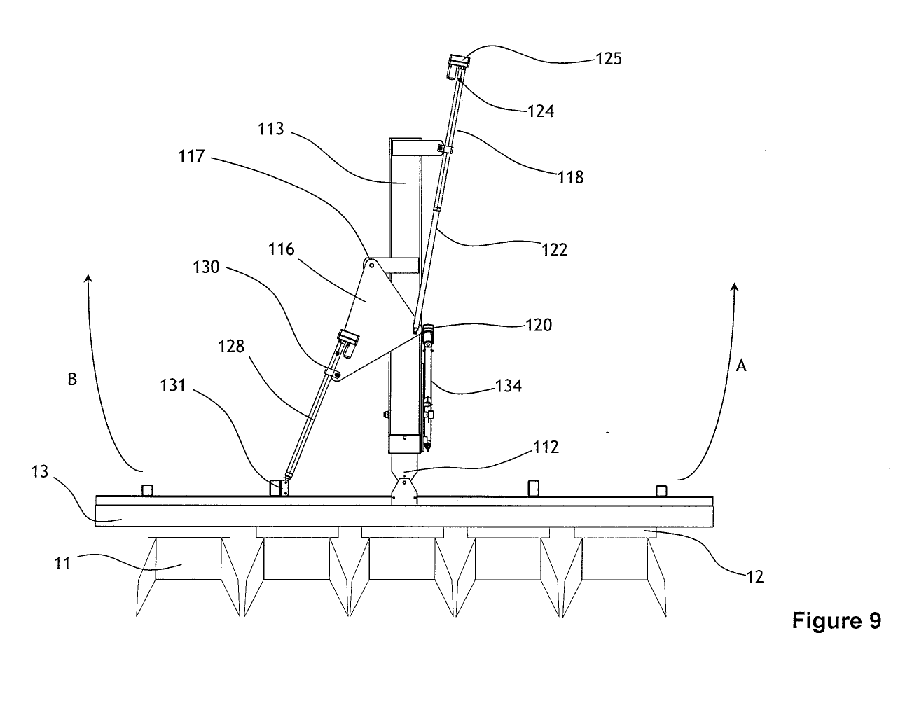

FIG. 9 is a plan view of the solar energy assembly and tracking assembly of FIGS. 7 and 8.

Referring initially to FIGS. 1 to 3, there is shown a reflector assembly comprising a reflector 11 and a frame 12 attached to a substrate 13 carrying a plurality of solar cells (photovoltaic cells) in an area 14 bound by the frame 12. The substrate 13 will, in a practical embodiment, be significantly larger than is shown in FIG. 1 and will support a large number of frames 12 each bounding an area within which is provided a plurality of solar cells. Typically, there may be a 10×10 array of such areas on a substrate which might measure 1600 mm×1600 mm and each individual area may measure about 80 mm×80 mm. This will give a collection ratio of about 4:1.

Each reflector 11 comprises four main panels 16 and four secondary panels 17, each panel being capable of reflecting incident solar radiation on to the solar cells within the area 14 bound by frame 12. Each main panel 16 is rectangular and has a lower edge 18 which lies alongside an edge of the frame 12 and a pair of opposed side edges 19 which extend perpendicularly to the lower edge 18. Each panel 16 also has a top edge 20 which extends parallel to the lower edge 18. Opposed pairs of main panels 16 flare outwardly from the frame 12, at an angle of about 60° to the perpendicular from the plane of the frame 12.

The secondary panels 17 are disposed between adjacent pairs of main panels 16 and are profiled such that each secondary panel has a pair of first edges 21 which mate with the side edges 19 of the two main panels 16 to each side of the secondary panel. The two first edges 21 of each secondary panel meet at a lower corner 22 which is disposed in a corner region of the frame 12, adjacent the junction of the lower edges 18 of the two adjacent main panels. Depending upon the materials from which the main and secondary panels 16 and 17 are made, typically the mating edges of the panels are bonded together by means of a high strength, high durability adhesive or maybe chemically fused together.

Each reflecting panel 16, 17 is made of an optically transparent (to solar radiation) material and has a planar front face 24. The rear face of each panel is formed with a plurality of ribs 25, the ribs extending parallel to the side edges 19 in the case of the main panels 16 and the ribs extending parallel to a line drawn between the lower corner 22 and an opposed upper corner 26 in the case of the secondary panels 17. Each rib is of triangular cross-sectional shape, as best seen in FIGS. 2 and 6 and has a pair of flanks 27 with an included angle of 90° therebetween. Having regard to the material of the panel and the included angle between flanks 27, the ribs 25 serve as prismatic units for effecting total internal reflection of solar radiation passing through the front face 24 of the panel so as to be incident internally on the flanks 27. In this way, solar radiation incident on the panel undergoes total internal reflection within the ribs 25, such that the radiation is then reflected to emerge from the front face 24 of the panel.

The main and secondary panels 16, 17 are typically made of a polycarbonate material which is both durable and optically transparent though inevitably there will be some attenuation of solar radiation on passing through the panel. The panels may be around 2.5 mm to 3 mm thick, depending upon the size of the ribs 25 formed on the rear faces of the panels. The efficiency of the prismatic total internal reflection units is strongly dependent upon the quality of the optical surfaces of the units and the tip radius at the apex of the units. These factors should be optimised in order to enhance the reflectivity of each panel.

The lower edge of the reflector 11, as a whole, is generally rectangular and defined primarily by the lower edges 18 of the main panels 16. Those lower edges fit within the rectangular frame 12 held to the substrate 13 by means of bolts or other. fasteners (not shown) passing through bores 29 formed in the corner regions 30 of the frame. In order to allow easy removal of a reflector 11 from the frame, for example in case of damage to the reflector or to allow cleaning, the reflector 11 is held to the frame by four releasable clips 31 disposed one at each corner region 30 of the frame. At each corner, a bar 32 projects laterally from the reflector 11 through an aperture 33 formed in the lower corner 22 of the secondary panel 17, the bar having a stepped profile as best seen in FIG. 6.

Each clip 31 comprises a carrier defining a slot 34 between a pair of arms 35 and a catch member 36 aligned with the slot and resiliently deformable outwardly away from the slot. The catch member includes a ramp profile 37 such that on offering a reflector 11 to the frame, the four bars 32 at each corner region of the reflector bear on the ramp profiles of the four catch members and deform those members outwardly as the bars are moved into the slots 34. When pushed fully home, the catch members engage over the top surfaces 38 of the bars 32 so holding the reflector 11 to the frame. When the reflector is to be removed from the frame, all that is necessary is for each of the four catch members to be sprung outwardly so releasing the bars and permitting removal of the reflector, as a whole.

The reflector assembly allows the building of a relatively large scale solar energy collector by having a plurality of the frames 12 disposed in an array on a substrate with the spacing between the frames such that when holding reflectors, the upper edges of those reflectors are closely adjacent each other. Solar cells mounted within the areas bound by the frames will have solar energy directed thereon in view of the reflective properties of the panels 16, 17 so allowing the generation of electricity from the incident solar radiation. The use of total internal reflection within the panels to effect the reflection of incident radiation is found to be highly efficient and less prone to degradation with time than would be expected with surface reflection, such as from a metallic film. Further, the front faces 24 of the panels are easy to clean in case they become covered with detritus, dust and so on but in the case of heavy contamination or damage, the reflectors may be removed with relative ease and be cleaned or replaced as required.

FIG. 7 shows a solar energy assembly generally indicated 105. This comprises a support pillar 106 that attaches to the ground 107 (represented by a block) and the substrate 13 of a solar panel attached to a T-shaped sub-frame 109 which in turn is pivotally connected to the top of the support pillar 106 about a horizontal axis. The solar panel comprise a large substrate 13 upon which multiple reflectors 11 and solar cells are mounted using frames 12 as described above (although for these are only visible in FIG. 9 as they are on the other side of the substrate). The solar panel is pivotally connected to the sub-frame 109 about a generally vertical axis, such that it may rotate to track the horizontal movement of the sun. The sub-frame 109 and attached solar panel may pivot about its connection to the support pillar in order to cause vertical tracking of the solar panel.

As can best be seen in FIGS. 8 and 9 the movement of the solar panel with respect to the support pillar is controlled by various actuators. The sub-frame 109 comprises a vertical member 112 and a horizontal member 113. A bracing plate 114 is connected across the union between the vertical member 112 and the horizontal member 113 to provide strength and also a pivot point for the connection to the upper end of the support pillar 106.

A generally triangular crank plate 116 is pivotally connected at a first corner 117 to the horizontal member 113. A first end 119 of a first linear actuator 118 is pivotally connected to a second corner 120 of the crank plate 116. The first end of the linear actuator 118 is the outer end of a reciprocating drive piston 122 which is capable of sliding backwards and forwards into a piston housing 124 under the control of a motor assembly 125. The drive piston 122, piston housing 124 and motor assembly 125 together comprise the actuator. The piston housing of the first linear actuator 118 is pivotally connected to the end of the horizontal member 113.

An equivalent second linear actuator 128 is pivotally connected to a third corner 130 of the crank plate 116. The outer end of the piston of the second linear actuator (which end is equivalent to the first end 119) is pivotally connected to the panel at bracket 131.

A third linear actuator 134 is pivotally connected to the vertical member 112 and the support pillar 106. The first, second and third linear actuators are all equivalent.

Horizontal tracking of the panel 108 is achieved by rotation of that panel with respect to the pillar 106 and vertical member 112. Operation of the first and second linear actuators 118 and 128 achieves this movement. In FIGS. 7-9 the panel is shown at approximately the middle of its range of movement. In practice in this configuration the panel would be directed towards the midday sun. To move the panel in the direction of arrow A (shown in FIG. 9) the first linear actuator 118 would remain fixed but the second linear actuator 128 would extend. Specifically the motor assembly would be operated to move its drive piston from within the piston housing thereby lengthening overall the actuator 128. This would force the panel to rotate with respect to the vertical member 112. Return movement back to the centre position could be accommodated by the contraction of the piston of the second linear actuator and or the contraction of the first linear actuator 118. Movement in the direction of arrow B would be achieved by the contraction of the first linear actuator 118. As the overall length of the first linear actuator 118 diminished as a result of the drive piston 122 sliding into the piston housing 124, the crank plate 116 would be forced to rotate in the direction of arrow C around the pivoting connection at the first corner 117 thereof. This would move the position of the third corner 130 and hence pull the panel by the second linear actuator to swing in the direction of arrow B.

Each piston housing 124 is connected by means that allow appropriate rotation but not sliding. This can conveniently be achieved by a tight clasp around the housing that is mounted in a rotatable fashion to the lateral member, crank or other part.

The motors of the three linear actuators may be linked to a control system that has light sensors so that tracking of the Sun is automated.

The tracking assembly is used to keep the solar collectors aligned with the sun during its daily movement. A significant advantage of this tracking assembly is that low cost linear actuators may be used for movement without limitation on the geometry of their action. Previously one could only achieve maximum movements of around +/−45 degrees, but the combination of two linear actuators and a crank as in the present invention can achieve a +/−80 degree movement.

1. A reflector for directing solar radiation on to energy converters provided within a defined area, which reflector is arranged for location around said area with a lower edge of the reflector positioned adjacent the periphery of said area, the reflector comprising a panel formed of a material substantially transparent to solar radiation and having a front face on to which solar radiation is incident, and behind the front face the reflector is formed to have a plurality of prismatic units within which total internal reflection of radiation incident on the front face takes place whereby in use solar radiation incident on the front face of the reflector is reflected within the reflector by the prismatic units to be directed on to the energy converters.

2. A reflector as claimed in claim 1, wherein each prismatic unit comprises a rib of substantially triangular cross-sectional shape extending across the panel.

3. A reflector as claimed in claim 2, wherein each rib has an included angle of substantially 90° between the flanks defining the rib.

4. A reflector as claimed in claim 2, wherein each rib extends from the lower edge of the panel to an opposed upper edge of the panel.

5. A reflector as claimed in claim 4, wherein each rib extends in alignment with a perpendicular to said defined area.

6. A reflector as claimed in claim 1, wherein the reflector comprises a plurality of generally rectangular main panels each having a lower edge for locating adjacent said area, each main panel also having a pair of side edges extending from and generally normal to the associated lower edge and each main panel flaring outwardly from said area, and a plurality of secondary panels each having an adjacent pair of first edges meeting at a lower corner adapted to locate at the junction between the lower edges of two adjacent main panels with the first edges of the secondary panels substantially mating with the side edges of the two adjacent main panels.

7. A reflector as claimed in claim 6, wherein the main panels flare outwardly at an angle within the range of 55° to 65° relative to a perpendicular from the plane of the frame.

8. A reflector as claimed in claim 7, wherein the main panels flare outwardly at an angle of substantially 60° relative to a perpendicular from the plane of the frame.

9. A reflector as claimed in claim 1, wherein each panel is formed of an optically transparent plastics material.

10. A solar energy assembly for collecting and converting solar energy, which assembly comprises a substrate supporting an array of energy converters, a frame mounted on the substrate to extend around at least some or part of the energy converters, and a reflector, as claimed in claim 1, carried by the frame and having at least one reflecting panels arranged to reflect incident solar energy on to the converters.

11. (canceled)

12. A solar energy assembly as claimed in claim 10, wherein there is at least one releasable clip which secures the reflector to the frame.

13. (canceled)

14. A solar energy assembly as claimed in claims 10, wherein the frame is of generally rectangular shape.

15. A solar energy assembly as claimed in claim 12, wherein there is provided a releasable clip at each corner region of the frame.

16. A solar energy assembly as claimed in claim 12, wherein each clip comprises a resiliently flexible catch member mounted on one of the frame and reflector and having a catch surface engageable with a lug projecting from the other of the frame and reflector.

17. A solar energy assembly as claimed in claim 16, wherein the catch member has a ramp surface engageable by the lug on moving the reflector into engagement with the frame whereby the catch member is deflected sufficiently to allow the lug to move behind the catch surface so as to be held by the catch member.

18. A solar energy assembly as claimed in claim 10, wherein the array of energy converters comprises an array of photovoltaic cells.

19. A solar energy assembly as claimed in claim 18, wherein the substrate supports a plurality of similar arrays of photovoltaic cells and there is provided a plurality of frames each surrounding a respective array and having associated therewith a respective reflector.

20. (canceled)

21. (canceled)

22. A solar energy assembly as claimed in claim 10, wherein the frame wholly surrounds the or each array of energy converters.

23. A solar energy assembly as claimed in claim 10, wherein the frame is provided with a plurality of bores extending perpendicularly to the plane of the frame and fasteners extend through those bores into the substrate thereby to mount the frame on the substrate.

24. A solar energy assembly as claimed in claim 10, wherein there is further provided a tracking assembly to move the substrate and supported components relative to a mounting.

25. A solar energy assembly as claimed in claim 24, wherein the tracking assembly comprises a crank, a first linear actuator connected to the mounting and the crank and a second linear actuator connected to the crank and the solar panel, whereby linear extension and/or contraction of one or both actuators causes rotational movement of the panel relative to the mounting about a first axis.

26. (canceled)

27. (canceled)

28. (canceled)

29. (canceled)

30. (canceled)

31. (canceled)

32. (canceled)

33. (canceled)

34. A solar energy assembly for collecting and converting solar energy, which assembly comprises a substrate supporting an array of energy converters, a frame mounted on the substrate to extend around at least some or part of the energy converters, and a reflector carried by the frame and having a plurality of reflecting panels arranged to reflect incident solar energy on to the converters, the reflector being releasably supported by the frame so as to be readily separable therefrom.
